(19) United States
(12) Patent Application Publication
(10) Pub. No.: US 2023/0289138 A1
(43) Pub. Date: Sep. 14, 2023

(54) HARDWARE DEVICE TO EXECUTE INSTRUCTION TO CONVERT INPUT VALUE FROM ONE DATA FORMAT TO ANOTHER DATA FORMAT

(71) Applicant: INTERNATIONAL BUSINESS MACHINES CORPORATION, Armonk, NY (US)

(72) Inventors: Petra Leber, Ehningen (DE); Kerstin Claudia Schelm, Stuttgart (DE); Cedric Lichtenau, Stuttgart (DE); Stefan Payer, Stuttgart (DE); Michael Klein, Schoenaich (DE); Silvia Melitta Mueller, St. Ingbert (DE)

(21) Appl. No.: 17/653,946

(22) Filed: Mar. 8, 2022

(51) Int. Cl. G06F 7/48

(52) U.S. Cl. CPC G06F 7/48

(57) ABSTRACT

A hardware device is provided to perform a plurality of operations to convert an input value directly from one format to another format. The hardware device is to perform the plurality of operations based on execution of an instruction. The plurality of operations includes scaling the input value to provide a scaled result and converting the scaled result from the one format to provide a converted result in the other format. The scaling and converting are to be performed as part of executing the instruction. The converted result in the other format is provided to be used in processing within the computing environment.

### BACKGROUND

One or more aspects relate, in general, to facilitating processing within a computing environment, and in particular, to improving such processing.

Applications executing within a computing environment provide many operations used by numerous types of technologies, including but not limited to, engineering, manufacturing, medical technologies, automotive technologies, computer processing, etc. These applications, written in a programming language, such as COBOL, often perform complex calculations in performing the operations. The calculations include, for instance, power and/or exponentiation functions, which often require conversion of data from one format (e.g., binary coded decimal) to another format (e.g., hexadecimal floating point), and vice versa.

In order for an application to perform the conversion from one format to another format, various steps and instructions are executed. For instance, to convert from binary coded decimal to hexadecimal floating point, an application includes steps/instructions to convert a binary coded decimal number to an integer number, then the integer number is converted to a hexadecimal floating point number. Further, to convert back to binary coded decimal, the hexadecimal floating point number is converted to an integer number, and then the integer number is converted to binary coded decimal. Moreover, each of those steps may include sub-steps. This is time-consuming, impacting performance of the computing environment, and affecting availability of computer resources.

### SUMMARY

Shortcomings of the prior art are overcome, and additional advantages are provided through the provision of a computer system for facilitating processing within a computing environment. The computer system includes a hardware device to perform a plurality of operations to convert an input value directly from one format to another format. The hardware device is to perform the plurality of operations based on execution of an instruction. The plurality of operations includes scaling the input value to provide a scaled result and converting the scaled result from the one format to provide a converted result in the other format. The scaling and converting are to be performed as part of executing the instruction. The converted result in the other format is provided to be used in processing within the computing environment.

By using the hardware device to perform the scaling and converting as part of executing an instruction, performance is improved, and use of system resources is reduced. In one aspect, the input value is converted directly from the one format to the other format within one instruction. That is, the value is converted without use of other instructions (e.g., other architected instructions at the hardware/software interface), including other convert instructions to convert the value into intermediate formats prior to the final format.

As examples, the one format is a binary coded decimal format, and the other format is a hexadecimal floating point format.

In one aspect, the hardware device includes a conversion component, and the conversion component is to scale the input value to provide the scaled result. Further, in one aspect, the conversion component is to perform at least part of the converting. The at least part of the converting includes converting the scaled result in the one format to provide a value in a representation of the other format. By performing the scaling in the conversion component prior to converting, use of processing cycles is reduced and performance is improved.

In one aspect, the hardware device further includes an arithmetic component to produce an intermediate fraction value in the other format based on the value in the representation of the other format.

In one aspect, the hardware device further includes a count leading zeros component to determine a number of leading zeros of the value in the representation of the other format.

In one aspect, the hardware device further includes an exponent component. The exponent component is to obtain the number of leading zeros to be determined by the count leading zeros component and to calculate a weight based on the number of leading zeros.

In one aspect, the hardware device further includes a shift component. The shift component is to obtain a shift amount based on the weight to be calculated by the exponent component and is to obtain the intermediate fraction value in the other format to be produced by the arithmetic component. The shift component is to perform a shift of the intermediate fraction value in a specified direction based on the shift amount to produce a resulting fraction.

In one aspect, the arithmetic component is to truncate the resulting fraction to provide a truncated fraction of a given precision. The truncated fraction is to be used to provide one portion of the converted result in the other format. In one aspect, the arithmetic component is to round the resulting fraction to provide a rounded fraction of a given precision. The rounded fraction is to be used to provide one portion of the converted result in the other format.

In one aspect, the resulting fraction is used to provide one portion of the converted result, and at least one component of the hardware device is to provide another portion of the converted result based on the input value and the weight.

In one aspect, the hardware device includes a shift component and a count leading zeros component. The shift component is to obtain the intermediate fraction value in the other format to be produced by the arithmetic component and to split the intermediate fraction value into one part and another part. The count leading zeros component is to determine a number of leading zeros of the one part and a number of leading zeros of the other part.

In one aspect, the hardware device further includes a normalize component to shift the one part a specified direction and a specified amount based at least on the number of leading zeros of the one part, to truncate remaining digits in a prespecified direction of the one part to provide a truncated one part and to move the truncated one part to a low order fractional part of the converted result in the other format.

In one aspect, the hardware device includes a normalize component to shift the other part a specified direction and a specified amount based at least on the number of leading zeros of the other part, to truncate remaining digits in a prespecified direction of the other part to provide a truncated another part and to move the truncated another part to a high order fractional part of the converted result in the other format.

In one example, the hardware device is a decimal floating point unit.

As one example, the converting includes converting the scaled result in the one format to provide a value in a representation of the another format, producing an intermediate fraction value in the other format based on the value in the representation of the other format, determining a number of leading zeros of the value in the representation of the other format, calculating a weight based on the number of leading zeros, performing a shift of the intermediate fraction value in a specified direction based on a shift amount determined based on the weight to provide a resulting fraction, and using the resulting fraction to provide the converted result.

By using the hardware device to perform the plurality of operations as part of executing an instruction, performance is improved, and use of system resources is reduced. Further, the speed at which conversions are performed is increased without losing precision compared to a software solution.

Computer-implemented methods and computer program products relating to one or more aspects are also described and may be claimed herein. Further, services relating to one or more aspects are also described and may be claimed herein.

Additional features and advantages are realized through the techniques described herein. Other embodiments and aspects are described in detail herein and are considered a part of the claimed aspects.

### BRIEF DESCRIPTION OF THE DRAWINGS

One or more aspects are particularly pointed out and distinctly claimed as examples in the claims at the conclusion of the specification. The foregoing and objects, features, and advantages of one or more aspects are apparent from the following detailed description taken in conjunction with the accompanying drawings in which:

FIG. 1 depicts one example of a computing environment to include and/or use one or more aspects of the present invention;

FIG. 2 depicts one example of processing to convert a value from one format (e.g., binary coded decimal) into another format (e.g., hexadecimal floating point), in accordance with one or more aspects of the present invention;

FIG. 3 depicts one example of components of a hardware device (e.g., a decimal floating point unit) to perform conversion of a value from one format (e.g., binary coded decimal) to another format (e.g., hexadecimal floating point), in accordance with one or more aspects of the present invention;

FIG. 4 depicts one example of processing to split an intermediate hexadecimal fraction into a low order part, in accordance with one or more aspects of the present invention;

FIG. 5 depicts one example of processing to split an intermediate hexadecimal fraction into a high order part, in accordance with one or more aspects of the present invention;

FIG. 6 depicts one example of a hardware device (e.g., a decimal floating point unit) to split an intermediate hexadecimal fraction into a low order part and a high order part, in accordance with one or more aspects of the present invention;

FIGS. 7A-7C depict one example of a hardware device and operations to be performed by the hardware device to convert an input value in one format to another format, in accordance with one or more aspects of the present invention;

FIG. 8A depicts another example of a computing environment to incorporate and/or use one or more aspects of the present invention;

FIG. 8B depicts further details of the memory of FIG. 8A, in accordance with one or more aspects of the present invention;

FIG. 9 depicts one embodiment of a cloud computing environment, in accordance with one or more aspects of the present invention; and

FIG. 10 depicts one example of abstraction model layers, in accordance with one or more aspects of the present invention.

### DETAILED DESCRIPTION

In one or more aspects, a capability is provided to facilitate processing within a computing environment. In one aspect, a single instruction (e.g., a single architected hardware machine instruction at the hardware/software interface) is provided to perform scale and then convert operations of an input value to convert the input value from one format (e.g., a binary coded decimal format) to another format (e.g., a hexadecimal floating point format). The instruction, referred to herein, for instance, as a Decimal Scale and Convert to Hexadecimal Floating Point instruction or a Vector Scale and Convert to Hexadecimal Floating Point instruction; or a Decimal Scale and Convert and Split to Hexadecimal Floating Point instruction or a Vector Scale and Convert and Split to Hexadecimal Floating Point instruction, is part of a general-purpose processor instruction set architecture (ISA), which is dispatched by a program on a processor, such as a general-purpose processor. (In another example, the instruction may be part of a special-purpose processor, such as a co-processor configured for certain functions.)

In one aspect, the single instruction is executed within one hardware device, such as a decimal floating point unit. The decimal floating point unit includes, for example, one or more hardware components, each composed of one or more circuits, to perform operations of the instruction to convert the input value. Although example components of the decimal floating point unit are described herein, the decimal floating point unit (or other hardware device) may include additional, fewer and/or other components to convert the input value.

As part of execution of the single instruction (e.g., the Decimal Scale and Convert to Hexadecimal Floating Point instruction or Vector Scale and Convert to Hexadecimal Floating Point instruction), various operations are performed including scaling an input value and converting the input value from one format (e.g., binary coded decimal) to another format (e.g., hexadecimal floating point). Each of these operations is performed as part of executing the single instruction within the decimal floating point unit, improving system performance, and reducing use of system resources.

In one example, as indicated, the conversion is from binary coded decimal to hexadecimal floating point. Binary coded decimal is a binary encoding of a decimal number, in which each decimal digit is represented by a fixed number of bits (e.g., 4 or 8 bits). Hexadecimal floating point is a format for encoding floating point numbers. In one example, a hexadecimal floating point number includes a sign bit, a characteristic (e.g., 7 bits) and a fraction (e.g., 6, 14 or 28 digits). The characteristic represents a signed exponent and is obtained by adding, e.g., 64 to the exponent value. The range of the characteristic is 0 to 127, which corresponds to an exponent range of, e.g., −64 to +63. The magnitude of a hexadecimal floating point number is the product of its fraction and the number 16 raised to the power of the exponent that is represented by its characteristic. The number is positive or negative depending on whether the sign bit is, e.g., zero or one, respectively.

A hexadecimal floating point number may be represented in a number of different formats, including a short format (e.g., 32-bit), a long format (e.g., 64-bit) and an extended format (e.g., 128-bit). In each format, the first bit (e.g., the first leftmost bit, bit 0) is the sign bit; the next selected number of bits (e.g., seven bits) are the characteristic, and in the short and long formats, the remaining bits are the fraction, which include, e.g., six or fourteen hexadecimal digits, respectively. In the extended format, the fraction is, e.g., a 28-digit fraction, and the extended hexadecimal floating point number consists of two long format numbers that are called the high-order and the low-order parts. The high-order part is any long hexadecimal floating point number. The fraction of the high-order part contains, e.g., the leftmost 14 hexadecimal digits of the 28-digit fraction, and the fraction of the low-order part contains, e.g., the rightmost 14 hexadecimal digits of the 28-digit fraction. The characteristic and sign of the high-order part are the characteristic and sign of the extended hexadecimal floating point number, and the sign and characteristic of the low-order part of an extended operand are ignored.

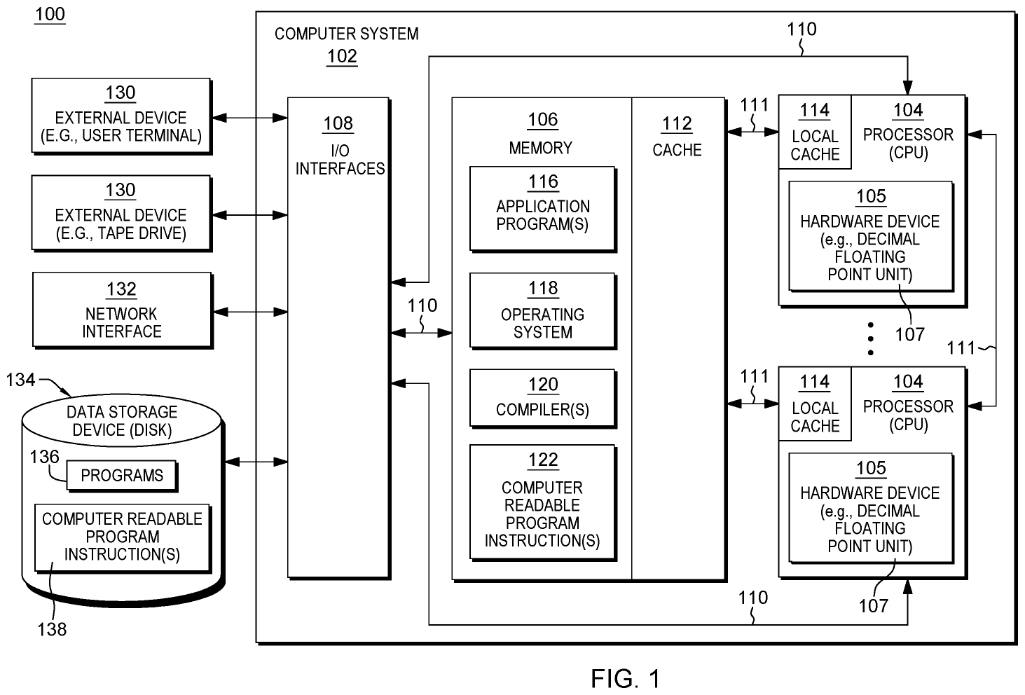

One embodiment of a computing environment to incorporate and use one or more aspects of the present invention is described with reference to FIG. 1. As an example, the computing environment is based on the IBM® z/Architecture® instruction set architecture, offered by International Business Machines Corporation, Armonk, N.Y. One embodiment of the z/Architecture instruction set architecture is described in a publication entitled, “z/Architecture Principles of Operation,” IBM Publication No. SA22-7832-12, Thirteenth Edition, September 2019, which is hereby incorporated herein by reference in its entirety. The z/Architecture instruction set architecture, however, is only one example architecture; other architectures and/or other types of computing environments of International Business Machines Corporation and/or of other entities may include and/or use one or more aspects of the present invention. IBM and z/Architecture are trademarks or registered trademarks of International Business Machines Corporation in at least one jurisdiction.

Referring to FIG. 1, in one example, a computing environment 100 includes, for instance, a computer system 102 shown, e.g., in the form of a general-purpose computing device. Computer system 102 may include, but is not limited to, one or more processors or processing units 104 (e.g., central processing units (CPUs) and/or special-purpose processors, etc.), a memory 106 (a.k.a., system memory, main memory, main storage, central storage or storage, as examples), and one or more input/output (I/O) interfaces 108, coupled to one another via one or more buses and/or other connections. For instance, processors 104 and memory 106 are coupled to I/O interfaces 108 via one or more buses 110, and processors 104 are coupled to one another via one or more buses 111.

Bus 111 is, for instance, a memory or cache coherence bus, and bus 110 represents one or more of any of several types of bus structures, including a memory bus or memory controller, a peripheral bus, an accelerated graphics port, and a processor or local bus using any of a variety of bus architectures. By way of example, and not limitation, such architectures include the Industry Standard Architecture (ISA), the Micro Channel Architecture (MCA), the Enhanced ISA (EISA), the Video Electronics Standards Association (VESA) local bus, and the Peripheral Component Interconnect (PCI).

Processor 104 may include, in one or more examples, one or more hardware devices 105, such as one or more decimal floating point units 107, to perform certain tasks. In one or more aspects, the tasks include converting values from one data format (e.g., binary coded decimal) to another data format (e.g., hexadecimal floating point). The use of a decimal floating point unit to perform a conversion improves performance and reduces system resources to be used for the converting. In one aspect, decimal floating point unit 107 performs the conversion based on execution of a single instruction (e.g., a Decimal Scale and Convert to Hexadecimal Floating Point instruction or Vector Scale and Convert to Hexadecimal Floating Point instruction; or Decimal Scale and Convert and Split to Hexadecimal Floating Point instruction or a Vector Scale and Convert and Split to Hexadecimal Floating Point instruction), in which various operations are performed including, for instance, scaling the input data providing scaled input data and converting the scaled input data in one format (e.g., binary coded decimal) to provide a value in another format (e.g., hexadecimal floating point). In one example, the converting includes converting at least a portion of the scaled input data in the one format to an intermediate fractional value in the other format. Further, optionally, decimal floating point unit 107 splits the intermediate fractional value providing a high order part and a low order part. Each of these operations is performed as part of executing the single instruction in the decimal floating point unit (or other hardware device), improving system performance, and reducing use of system resources.

As examples, a decimal floating point unit 107 (or other hardware device 105) may be embedded within a processor, such as processor 104, and/or separate therefrom.

Memory 106 may include, for instance, a cache 112, such as a shared cache, which may be coupled to local caches 114 of one or more processors 104 via, e.g., one or more buses 111. Further, memory 106 may include one or more programs or applications 116, at least one operating system 118, one or more compilers 120 and one or more computer readable program instructions 122. Computer readable program instructions 122 may be configured to carry out functions of embodiments of aspects of the invention.

Computer system 102 may communicate via, e.g., I/O interfaces 108 with one or more external devices 130, such as a user terminal, a tape drive, a pointing device, a display, and one or more data storage devices 134, etc. A data storage device 134 may store one or more programs 136, one or more computer readable program instructions 138, and/or data, etc. The computer readable program instructions may be configured to carry out functions of embodiments of aspects of the invention.

Computer system 102 may also communicate via, e.g., I/O interfaces 108 with network interface 132, which enables computer system 102 to communicate with one or more networks, such as a local area network (LAN), a general wide area network (WAN), and/or a public network (e.g., the Internet), providing communication with other computing devices or systems.

Computer system 102 may include and/or be coupled to removable/non-removable, volatile/non-volatile computer system storage media. For example, it may include and/or be coupled to a non-removable, non-volatile magnetic media (typically called a “hard drive”), a magnetic disk drive for reading from and writing to a removable, non-volatile magnetic disk (e.g., a “floppy disk”), and/or an optical disk drive for reading from or writing to a removable, non-volatile optical disk, such as a CD-ROM, DVD-ROM or other optical media. It should be understood that other hardware and/or software components could be used in conjunction with computer system 102. Examples, include, but are not limited to: microcode, device drivers, redundant processing units, external disk drive arrays, RAID systems, tape drives, and data archival storage systems, etc.

Computer system 102 may be operational with numerous other general-purpose or special purpose computing system environments or configurations. Examples of well-known computing systems, environments, and/or configurations that may be suitable for use with computer system 102 include, but are not limited to, personal computer (PC) systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

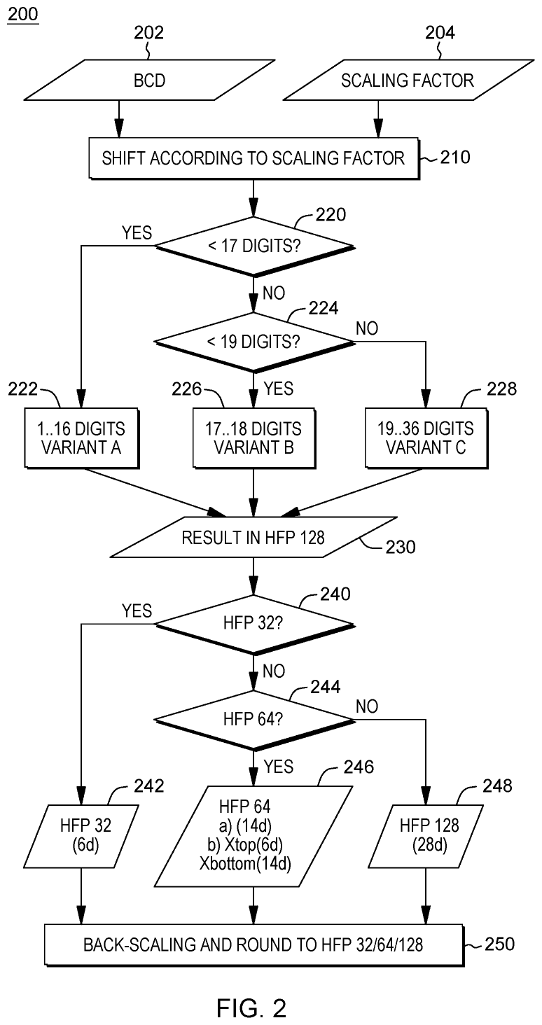

As indicated, in one aspect, a computing environment (e.g., processor 104 of computing environment 100) is used to convert an input value from one format (e.g., binary coded decimal) to another format (e.g., hexadecimal floating point). An overview of such a conversion is described with reference to FIG. 2.

Referring to FIG. 2, a conversion process 200 obtains an input value (also referred to as input data) 202 and a scaling factor 204. Input value 202 is, for instance, a scaled binary coded decimal number in the form p.v, where p is a number of integer digits and v is a number of fraction digits. Input value 202 is shifted 210 by scaling factor 204 such that the number of fraction digits is a multiple of a select number, e.g., 6.

The shifted number is then converted into a hexadecimal floating point number of a select size (e.g., 128 bits) using different code sequences dependent on the number of significant digits due to a limited internal number format. For instance, a determination is made as to whether the shifted number has less than a predefined number of digits (e.g., 17 digits) 220. If the shifted number has less than the predefined number of digits (e.g., digits 1 to 16), then the shifted number is converted 222 using a select code sequence A (described below) to provide a result 230 (e.g., a 128-bit hexadecimal floating point number).

Returning to inquiry 220, if the shifted number has greater than or equal to the predefined number of digits, then a further inquiry is made as to whether the shifted number has less than a further predefined number of digits (e.g., 19 digits) 224. If the shifted number has less than the further predefined number of digits (e.g., digits 17 to 18), then the shifted number is converted 226 using a select code sequence B (described below) to provide a result 230 (e.g., a 128-bit hexadecimal floating point number).

Returning to inquiry 224, if the shifted number has greater than or equal to the further predefined number of digits (e.g., digits 19 to 36), then the shifted number is converted 228 using a select code sequence C (described below) to provide a result 230 (e.g., a 128-bit hexadecimal floating point number).

Further, in one example, the 128-bit hexadecimal floating point number resulting from the above conversion is back-scaled and rounded depending on the target precision (e.g., 32 bits, 64 bits, 128 bits). Thus, in one example, a determination is made as to whether the 128-bit hexadecimal floating point number is to be represented as a 32-bit hexadecimal floating point result 240. If so, the 128-bit result is converted to a 32-bit hexadecimal floating point number 242 having, e.g., 6 digits by performing back-scaling and/or rounding 250. However, if the 128-bit result is not to be represented as a 32-bit hexadecimal floating point result, then a further determination is made as to whether the 128-bit result is to be represented as a 64-bit result 244. If the 128-bit hexadecimal number is to be represented in 64 bits, then the 128-bit result is converted to a 64-bit hexadecimal floating point number 246 having, e.g., 14 digits by performing back-scaling and/or rounding 250. Further, if the 128-bit hexadecimal floating point result is to be represented as a 128-bit result, then the 128-bit hexadecimal floating point result at 230 is back-scaled and/or rounded 250 to provide a 128-bit hexadecimal floating point number having, e.g., 28 digits (248).

Examples of code sequences A, B and C are provided below. Although these example sequences are provided, additional, fewer and/or other code sequences, instructions, etc. may be used. Code sequences A, B and C are just one set of examples.

Code Sequence A:

BCD after shifting has 1 . . . 16 digits
Representable with 14 Hex digits
Code:
Shift to prepare for convert
   SRP 369(7,R10),1,0
BCD to Bin(64b) to Hex(64b) to Hex(128b) conversion
   CVBG R0,360(R10)
   CDGR FP0,R0
   LXDR FP8,FP0

Code Sequence B:

BCD after shifting has 17 . . . 18 digits
Representable as 64-bit integer but requires more than 14 Hex digits
Code:
Shift to prepare for convert
   SRP 369(7,R10),1,0
BCD to Bin(64b) to Hex(128b) conversion
   CVBG R0,360(R10)
   CXGR FP0,R0

Code Sequence C:

BCD after shifting has 19 . . . 31 digits
Representable with 26 Hex digits, but not representable as 64-bit integer
Code:
Shift to prepare for convert
   SRP 383(9,R10),4,0
   MVHHI 376(,R10), X′0000′
bottom 15 digits conversion
   CVBG R1,376(,R10)
   CXGR FP4,R1
load 10\hat{ }16 to FP (floating point) registers
   LARL R1,L0016,offset=0x1FA
   LD FP8,336(,R1)
   LD FP10,344(,R1)
top 16 digits
   MVO 368(8,R10),362(7,R10)
   MVGHI 360(,R10),X′0000
   CVBG R1,360(,R10)
   CDGR FP1,R1
top 16 digits*10\hat{ }16+bottom
   LXDR FP0,FP1
   MXR FP0,FP8
   AXR FP0,FP4
   LDR FP1,FP0
   LXDR FP12,FP1

As shown, in the above code, various instructions (e.g., machine instructions at the hardware/software interface), such as, for example, shift instructions (e.g., Shift and Round Decimal-SRP); convert (e.g., Convert to Binary-CVBG, Convert to Fixed-CDGR, CXGR); load instructions (e.g., Load Lengthened-LXDR; Load-LDR, LD); move instructions (e.g., Move-MVHHI, MVGHI; Move with Offset-MVO); multiply instructions (e.g., Multiply-MXR); and add instructions (e.g., Add Normalized-AXR), are used to convert an input value from one format (e.g., binary coded decimal) to another format (e.g., hexadecimal floating point). However, in accordance with one or more aspects of the present invention, instead of executing the above instructions to convert a binary coded decimal value to a hexadecimal floating point value, a single instruction at the hardware/software interface (e.g., a Decimal Scale and Convert to Hexadecimal Floating Point instruction or Vector Scale and Convert to Hexadecimal Floating Point instruction; or a Decimal Scale and Convert and Split to Hexadecimal Floating Point instruction or a Vector Scale and Convert and Split to Hexadecimal Floating Point instruction) is executed to perform the conversion. The single instruction, when executed, causes an execution flow to commence in a hardware device (e.g., hardware device 105), such as a decimal floating point unit (e.g., decimal floating point unit 107).

In accordance with one or more aspects, operations 202-242 of FIG. 2 are performed by one instruction executed in a selected hardware device, such as a decimal floating point unit (e.g., decimal floating point unit 107). This instruction, referred to herein as a Decimal Scale and Convert to Hexadecimal Floating Point instruction or a Vector Scale and Convert to Hexadecimal Floating Point instruction, is a single architected hardware machine instruction at the hardware/software interface that replaces code sequence A. Similarly, operations 202-240, 244 and 246 are performed by one instruction executed in a selected hardware device, such as decimal floating point unit 107. This instruction, referred to herein as a Decimal Scale and Convert to Hexadecimal Floating Point instruction or a Vector Scale and Convert to Hexadecimal Floating Point instruction, is a single architected hardware machine instruction at the hardware/software interface that replaces code sequence B. Alternatively, another instruction, referred to herein as a Decimal Scale and Convert and Split to Hexadecimal Floating Point instruction or a Vector Scale and Convert and Split to Hexadecimal Floating Point instruction used to split an intermediate fractional value, as described further below, may be used to convert a binary coded decimal to hexadecimal floating point. Moreover, operations 202-240, 244 and 248 are performed by one instruction executed in a selected hardware device, such as decimal floating point unit 107. This instruction, referred to herein as a Decimal Scale and Convert to Hexadecimal Floating Point instruction or a Vector Scale and Convert to Hexadecimal Floating Point instruction, is a single architected hardware machine instruction at the hardware/software interface that replaces code sequence C. By using a single instruction and one hardware device (e.g., hardware device 105, such as decimal floating point unit 107), performance is improved, and fewer system resources are utilized.

In one aspect, a decimal floating point unit (e.g., decimal floating point unit 107 or other hardware device) is configured to directly convert an input value from one format (e.g., a decimal format, such as binary coded decimal) to another format (e.g., a hexadecimal floating point format), based on execution of and within a single instruction (e.g., a single architected hardware machine instruction at the hardware/software interface, e.g., a Decimal Scale and Convert to Hexadecimal Floating Point instruction or a Vector Scale and Convert to Hexadecimal Floating Point instruction; or a Decimal Scale and Convert and Split to Hexadecimal Floating Point instruction or a Vector Scale and Convert and Split to Hexadecimal Floating Point instruction). For instance, the scaling and conversion are performed within one instruction and within one unit, decimal floating point unit 107. The decimal floating point unit is configured and used to shift the binary coded decimal number and, at least, to convert the shifted number to an intermediate hexadecimal fraction. Further, the fraction is rounded and formatted to a given hexadecimal floating point precision.

Within the decimal floating point unit, in one example, a digit shift is introduced before the input latch to binary coded decimal to binary conversion hardware, in accordance with one or more aspects. Binary coded decimal to binary conversion hardware (e.g., a conversion component) within the decimal floating point unit is used and the output is treated as a hexadecimal fraction in, e.g., a sum and carry representation. The sum and carry are added together in an adder (e.g., an arithmetic component of the decimal floating point unit) to build an intermediate hexadecimal fraction. Further, in parallel (or substantially in parallel), a leading zero anticipator (e.g., a count leading zeros component) generates the leading zero digit count of the intermediate hexadecimal fraction. Based on the number of leading zero digits, a weight of the hexadecimal floating point number is calculated by, e.g., an exponent component of the decimal floating point unit. The intermediate hexadecimal fraction is piped back in the decimal floating point unit to an aligner (e.g., a shift component) where the fraction is shifted according to at least one of the target precision and the leading zero count. The shifted fraction is piped a second time through the adder, where it is optionally rounded and/or truncated. The rounded/truncated fraction is, e.g., normalized (e.g., a normalize component within the decimal floating point unit) to obtain a final hexadecimal floating point number.

By configuring the decimal floating point unit to directly convert input data from one format (e.g., a decimal format, such as binary coded decimal) to another format (e.g., a hexadecimal floating point format) within execution of a single instruction, processing within the computer is improved by, for instance, reducing processing cycles used to perform the conversion and reducing system resources.

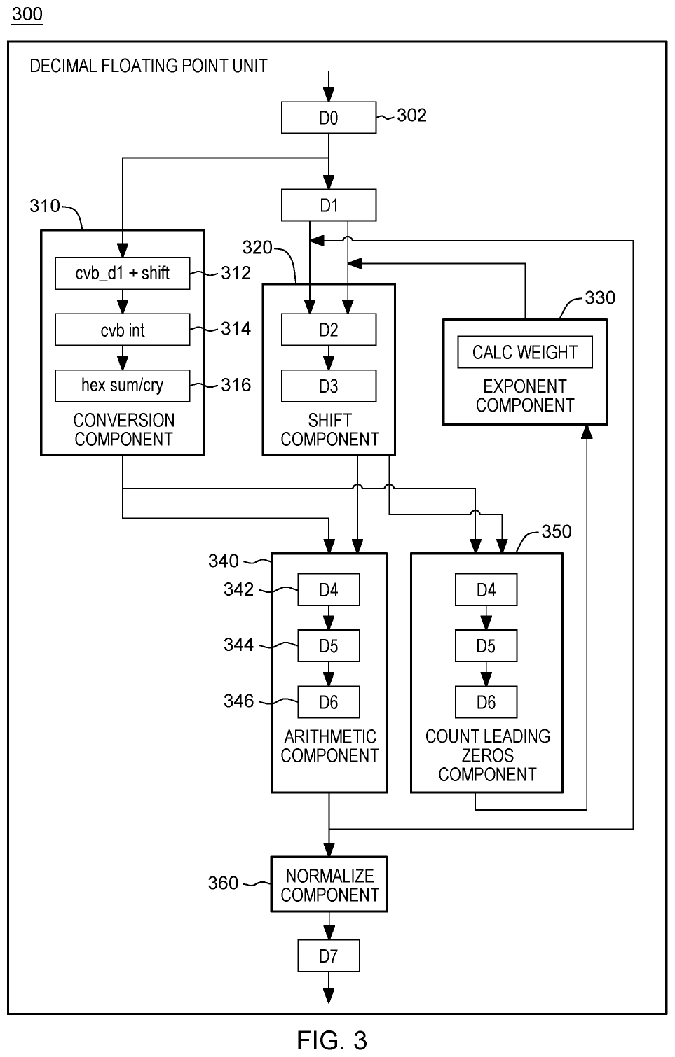

One example of a decimal floating point unit (e.g., decimal floating point unit 107) configured and used to directly convert input data from one format (e.g., a decimal format, such as binary coded decimal) to another format (e.g., a hexadecimal floating point format) is described with reference to FIG. 3. In one example, a decimal floating point unit 300 is a hardware device that includes a plurality of hardware components, including, for instance, a conversion component 310, a shift component 320, an exponent component 330, an arithmetic component 340, a count leading zeros component 350 and a normalize component 360. As an example, conversion component 310 is coupled to arithmetic component 340 and count leading zeros component 350. Further, shift component 320 is coupled to arithmetic component 340 and count leading zeros component 350. Count leading zeros component 350 is also coupled to exponent component 330, which is further coupled to shift component 320. Arithmetic component 340 is further coupled to normalize component 360. For instance, outputs of conversion component 310 and shift component 320 are input to arithmetic component 340 and count leading zeros component 350. An output of count leading zeros component 350 is input to exponent component 330. Outputs of arithmetic component 340 and exponent component 330 are input to shift component 320. Further, output of arithmetic component 340 is input to normalize component 360. Each component is composed of one or more circuits used to perform various operations. Further, a decimal floating point unit may have additional, fewer and/or other components. Moreover, although a particular component is described herein as performing a particular operation, that operation (or aspects thereof) may be performed by additional and/or other components.

Decimal floating point unit 300 obtains (e.g., receives, is provided, pulls, etc.) data to be converted, based on execution of an instruction, such as a convert from binary coded decimal to hexadecimal floating point instruction (e.g., a Decimal Scale and Convert to Hexadecimal Floating Point instruction or a Vector Scale and Convert to Hexadecimal Floating Point instruction; or a Decimal Scale and Convert and Split to Hexadecimal Floating Point instruction or a Vector Scale and Convert and Split to Hexadecimal Floating Point instruction, etc.) commencing on a processor, such as processor 104. Within execution of the instruction, the data, e.g., a binary coded decimal number, which is, for example, an input of the instruction, is obtained by decimal floating point unit 300 at a processing cycle DO (302). During processing cycle D0, the data is input to conversion component 310 that scales, in accordance with an aspect of the present invention, the binary coded decimal number and converts the scaled number into a value. For instance, the binary coded decimal number is shifted 312 by a scale factor in a prespecified direction (e.g., the left) providing an integer value 314 represented as a hexadecimal sum and carry 316. In one example, processing (e.g., of 314, 316) within the conversion component may loop to convert the scaled binary coded decimal number into the integer value represented as a hexadecimal sum and carry, referred to herein as a hexadecimal fractional representation.

The hexadecimal fractional representation is input to arithmetic component 340 in which during, e.g., cycles D4-D6 (342-346), the sum and carry are added together to provide an intermediate hexadecimal fraction. The intermediate hexadecimal fraction is provided to shift component 320.

Moreover, in one example, in parallel or substantially in parallel (e.g., at least a portion of the processing is performed at the same time) to the processing in arithmetic component 340, count leading zeros component 350 counts (e.g., during processing cycles D4-D6) the leading zeros of the value represented as a hexadecimal sum and carry. An output of count leading zeros component 350 is input to exponent component 330 that calculates a weight (i.e., correct exponent) of the hexadecimal floating point number based on the leading zeros. For instance, assume the inputs to arithmetic component 340 are: 00_00047_2AB35_89EF1_03456_0DC23_01019 (sum) and 00_000EF_12456_AB250_378AB_12DC7_39989 (carry). A result of adding the sum and carry in the arithmetic component is an intermediate fraction, which is input to shift component 320. For instance, the intermediate fraction is 00_00136_3CF8C_35141_3ADO1_209EA_3A9A2, with a result of leading zero count=4. In a hexadecimal floating point representation (with unlimited fraction), this is: 16\hat{ }28*0.1363CF8C351413AD01209EA3A9A2. There are 32 digits with 4 leading zeros→28 fraction digits. Thus the weight=32 digits−#leading zeros (4)=28.

An output of exponent component 330, a shift amount (e.g., 4, in this example) which is based on the weight and/or the number of leading zeros, is input to shift component 320.

In one aspect, shift component 320 shifts the intermediate hexadecimal fraction in a specified direction (e.g., left) according to at least one of the target precision and the shift amount and that resulting value is input to arithmetic component 340 and count leading zeros component 350. Arithmetic component 340, in one example, rounds and/or truncates the resulting value (e.g., the shifted intermediate hexadecimal fraction) to the given target precision in, e.g., processing cycle D6. Rounding and/or truncating allows further optimization in program code, such as COBOL code. In rounding, there can be an additional digit gained on, e.g., the left due to the rounding (which is performed in the arithmetic component during a second pass through the arithmetic component). The exponent, in this instance, is, e.g., adjusted in the exponent component and there is a signal from the arithmetic component to the exponent component to indicate that the adjustment is to be performed. The rounded/truncated fraction is, in one example, normalized (e.g., using normalize component 360) to provide a final fractional portion. The final fractional portion is used to provide a hexadecimal floating point number representing the binary coded decimal number provided as input to the instruction. The final hexadecimal floating point number, includes, for instance, a sign, a characteristic (based on the exponent), and a resulting fractional value (e.g., the resulting value) optionally, rounded, truncated and/or normalized.

Thus, in accordance with an aspect of the present invention, a hardware device, such as a decimal floating point unit, is configured and used to execute a shift on a binary coded decimal number followed by converting the shifted number to provide an intermediate hexadecimal fraction and rounding and formatting the fraction to be used to provide a given hexadecimal floating point precision in one architected instruction. This improves performance within a processor by, for instance, improving program code performance, such as COBOL performance, and/or reducing the number of processing cycles used in the conversion, which saves time and resources, thereby improving execution of a processor, computer system and/or computing environment in which the hardware device is used and/or associated with.

Further, in one aspect, the decimal floating point unit (or other hardware device) is configured and used to split the intermediate hexadecimal floating point number into multiple parts, such as a normalized top part (referred to herein as xTop) and a normalized bottom part (referred to herein as xBot). The top part represents the high order part of a hexadecimal floating point fraction, and the bottom part represents the low order part of the hexadecimal floating point fraction. Each part of the split result may be used independently of another part and/or selected parts may be used together to provide a result with greater precision. The split is performed as part of executing the single instruction and within the decimal floating point unit (e.g., decimal floating point unit 107 or other hardware device 105), improving system performance, and reducing use of system resources.

In one example, to perform the split, the conversion up to the addition of the sum/carry, the calculation of the leading zeros and the back piping to the shift component is as described above. After piping back to the shift component, in one example, the intermediate hexadecimal fraction is placed into two registers, e.g., register A and register B. The intermediate hexadecimal fraction in register A is shifted a specified direction (e.g., left) the number of leading zeros plus a prespecified number of digits (e.g., 6) inside the shift component. Selected digits (e.g., the leftmost 6 non-zero digits) represent the top part and are shifted out. The remaining digits represent the bottom part. The bottom part is passed through the arithmetic component and the count leading zeros component in which the leading zeros are calculated. Depending on the number of leading zero digits, the bottom part is normalized and/or truncated to a select number of digits (e.g., 14). The final bottom part is held for one cycle.

The intermediate hexadecimal fraction in register B is passed through the arithmetic component after holding for one cycle, in one example, so that the calculations are done one cycle after the calculations of the value in register A. The intermediate hexadecimal fraction in register B is passed through the arithmetic component and the count leading zeros component where the leading zeros are calculated. Depending on the number of leading zero digits, the top part is normalized and/or truncated to a select number of digits (e.g., 6). The top part, including the sign and exponent, is placed in the high part of the 128-bit result register with forcing the remaining select number of digits (e.g., 8 rightmost digits) to zero. The bottom part including the sign and exponent is placed in the low order part of the 128-bit result register. The weight of the top and the weight of the bottom part is taken to calculate the respective exponent values by taking the corresponding number of leading zero digits into account.

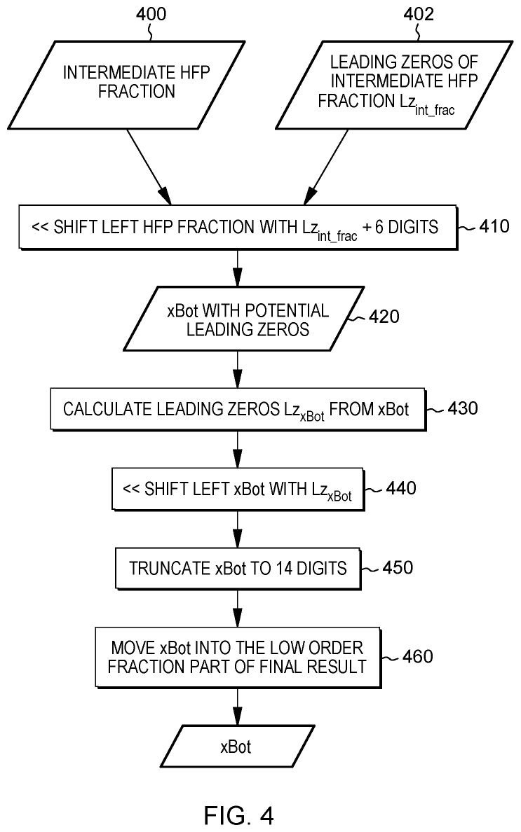

One embodiment of performing the split is described with reference to FIGS. 4-6. Based on executing an instruction (e.g., a Decimal Scale and Convert and Split to Hexadecimal Floating Point instruction or a Vector Scale and Convert and Split to Hexadecimal Floating Point instruction, etc.), an intermediate hexadecimal floating point fraction is generated, and processing is performed by, e.g., decimal floating point unit 107 to split the fraction into multiple parts, referred to herein as the low order part or xBot and the high order part or xTop.

Referring initially to FIG. 4, one embodiment of generating the low order part is described. In one example, an intermediate hexadecimal floating point fraction 400 is shifted (e.g., by shift component 320) in a select direction (e.g., left) 410 by a specified number of digits (e.g., the determined number of leading zeros 402 of the intermediate hexadecimal floating point fraction plus a select number of digits (e.g., 6)). A result of this shift is the low order part, xBot, with potential leading zeros 420. A determination is made (e.g., by count leading zeros component 350) as to the number of leading zeros of xBot 430. If there are leading zeros for xBot, xBot is shifted (e.g., by normalize component 360) in a select direction (e.g., left) by the number of leading zeros 440. The shifted xBot value is then, in one example, truncated (e.g., by normalize component 360) to a select number of digits (e.g., 14) 450. The truncated xBot is then moved into the low order fractional part of a final 128-bit result 460.

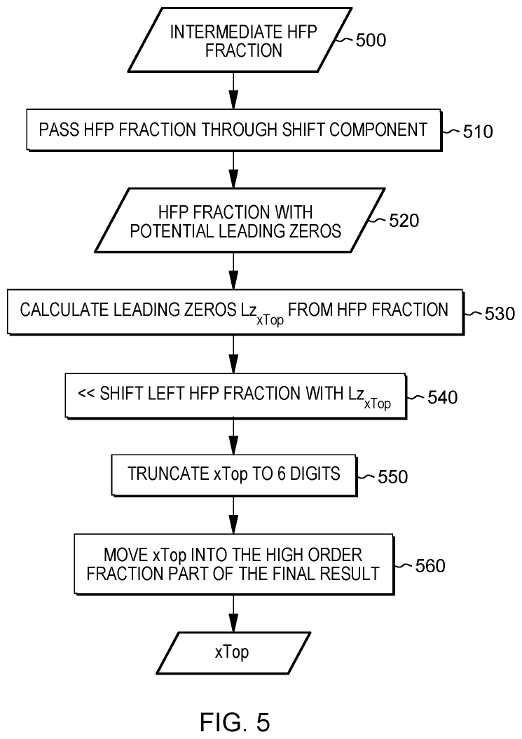

Additionally, in one example, the high order part, xTop, is generated. One embodiment of generating xTop is described with reference to FIG. 5. In one example, an intermediate hexadecimal floating point fraction 500 is passed through a shift component (e.g., shift component 320) 510. The hexadecimal floating point fraction with potential leading zeros 520 is passed to a count of leading zeros component (e.g., count leading zeros component 350), and a determination is made of the number of leading zeros of the hexadecimal floating point fraction 530. The hexadecimal floating point fraction is shifted (e.g., via normalize component 360) in a select direction (e.g., left) by the number of leading zeros, if any 540. The shifted value is then, in one example, truncated (e.g., by normalize component 360) to a select number of digits (e.g., 6) 550. The truncated xTop is then moved into the high order fractional part of a final 128-bit result 560.

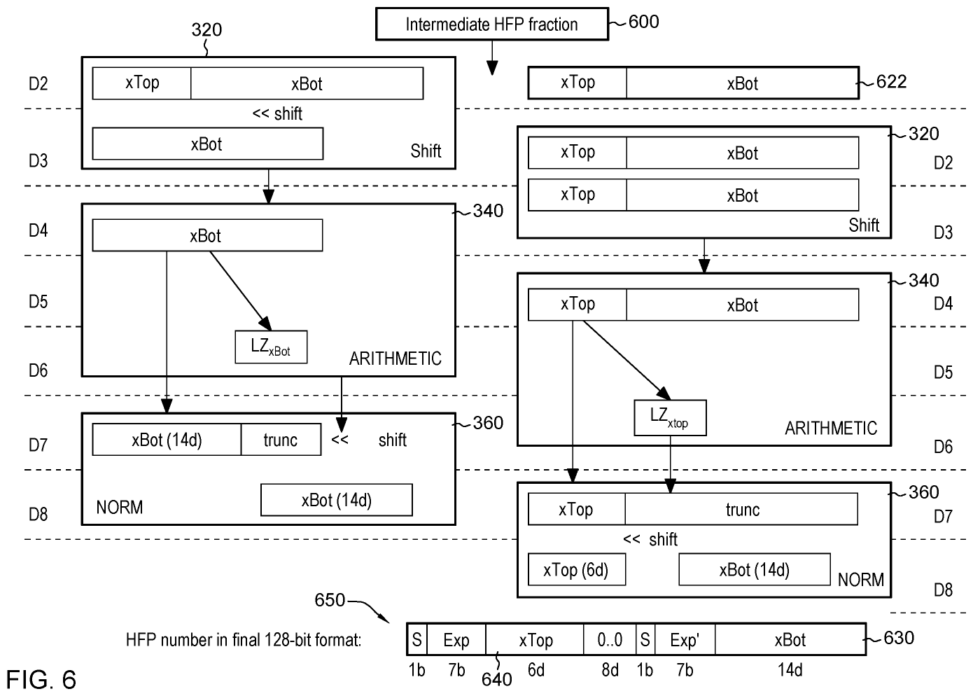

Further details with respect to splitting the hexadecimal floating point fraction are described with reference to FIG. 6. In one example, an intermediate hexadecimal floating point fraction 600 is input to shift component 320 in which the number is shifted in a select direction (e.g., left) by a select number of digits (e.g., the number of leading zeros plus a prespecified number of digits (e.g., 6)). The shifted result (e.g., xBot) is input to a count leading zeros component, which may be part of arithmetic component 340 or separate therefrom (e.g., count leading zeros component 350). The count leading zeros component determines the number of leading zeros of xBot. The shifted result, xBot, and the number of leading zeros is input to normalize component 360, which shifts in the select direction (e.g., left) the number of leading zeros of xBot. (Normalize component 360 may be a separate component of the decimal floating point unit or part of another component, such as shift component 320 or arithmetic component 340, as examples.) Further, the remaining digits in another select direction (e.g., right) of xBot are truncated using, e.g., normalize component 360. The result (e.g., 14 digit xBot) is moved into the low order fraction part 630 of a final 128-bit-result 650.

Further, in one example, with reference to FIG. 6, xTop is generated. For instance, the intermediate hexadecimal floating point fraction is held one cycle (622) and then shift component 320 passes the intermediate hexadecimal floating point fraction to a count leading zeros component which may be part of arithmetic component 340 or separate therefrom (e.g., count leading zeros component 350). The count leading zeros component determines the number of leading zeros of xTop. The shifted result, xTop, and the count of leading zeros is input to normalize component 360, which shifts in the select direction (e.g., left) the number of leading zeros of xTop. Further, the remaining digits in another selected direction (e.g., right) of xTop are truncated using, e.g., normalize component 360. The result (e.g., 6 digit xTop) is moved into a high order fraction part 640 of the final 128-bit result 650.

Thus, in accordance with one or more aspects of the present invention, a hardware device, such as a decimal floating point unit, is configured and used to execute a shift on a binary coded decimal number followed by converting the shifted number to an intermediate hexadecimal fraction and splitting the intermediate hexadecimal fraction into a normalized top part and a normalized bottom part, which represent the intermediate hexadecimal floating point number.

One or more aspects of the present invention are inextricably tied to computer technology and facilitate processing within a computer, improving performance thereof. The use of a hardware device, such as a decimal floating point unit, to perform conversions from one data format to another data format within execution of a single instruction improves processing within a processor, computer system and/or computing environment; reduces program code and the number of instructions (at the hardware/software interface) that are used; increases processing speed by reducing the number of processing cycles; and reduces use of system resources. Thus, the functioning of a processor, computer system and/or computing environment in which the decimal floating point unit is included and/or associated with is improved.

Further, in one or more aspects, the use of a hardware device, such as a decimal floating point unit, to perform scale, convert and optionally split operations within execution of a single instruction to convert an input value from one format, such as a binary coded decimal format, to another format, such as a hexadecimal floating point format, increases the speed at which such conversions are performed without losing precision compared to a software solution. By increasing the speed at which a conversion is performed, processing associated with transactions (executing on a processor, e.g., processor 104) that use those converted values is improved providing a high performance environment to execute those transactions (e.g., COBOL transactions). Again, processing within a processor, computer system and/or computing environment is improved.

Moreover, by improving conversion processing and processing associated with transactions and/or other processing that uses the converted results, improvements in technologies that use those transactions and/or other processing is also realized. These technologies include, but are not limited to, engineering, manufacturing, medical technologies, automotive technologies, computer processing, etc.

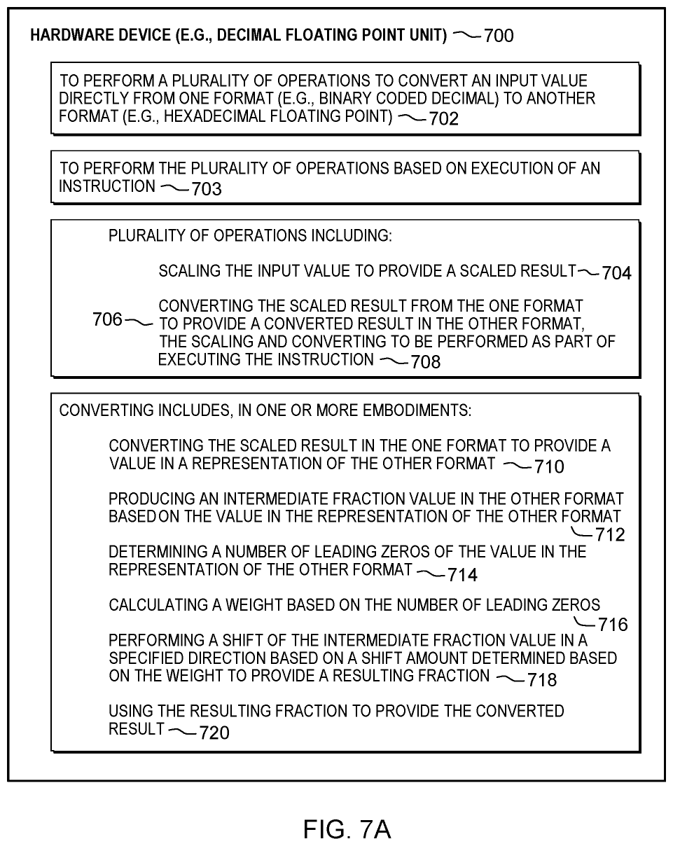

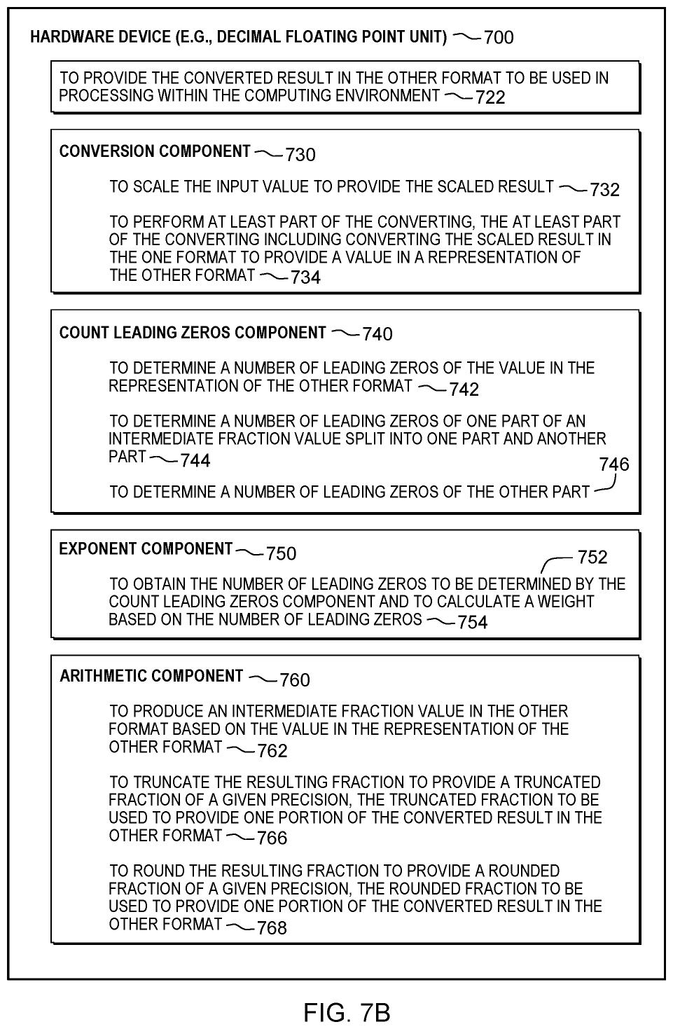

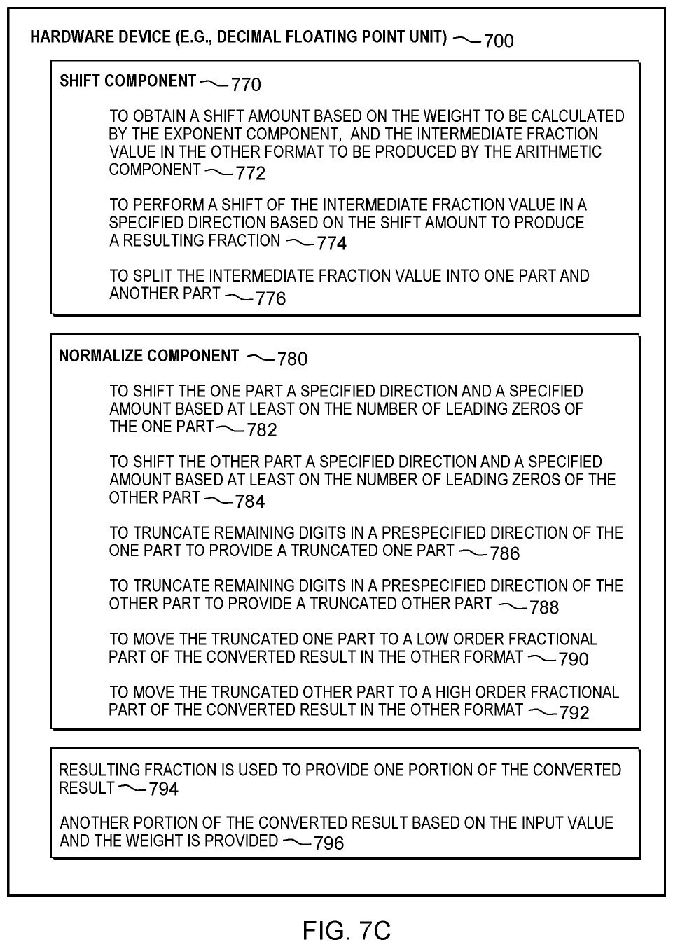

Further details of one embodiment of facilitating processing within a computing environment, as it relates to one or more aspects of the present invention, are described with reference to FIGS. 7A-7C.

Referring to FIG. 7A, in one aspect, a hardware device (e.g., a decimal floating point unit) 700 is to perform a plurality of operations to convert an input value directly from one format (e.g., binary coded decimal) to another format (e.g., hexadecimal floating point) 702. The hardware device is to perform the plurality of operations based on execution of an instruction 703. The plurality of operations includes, for instance, scaling the input value to provide a scaled result 704, and converting the scaled result from the one format to provide a converted result in the other format 706. The scaling and converting are to be performed as part of executing the instruction 708.

By using the hardware device to perform the scaling and converting as part of executing an instruction, performance is improved, and use of system resources is reduced. In one aspect, the input value is converted directly from the one format to the other format within one instruction. That is, the value is converted without use of other instructions (e.g., architected instructions at the hardware/software interface), including other convert instructions to convert the value into intermediate formats prior to the final format.

In one or more embodiments, the converting includes converting the scaled result in the one format to provide a value in a representation of the other format 710, producing an intermediate fraction value in the other format based on the value in the representation of the other format 712, determining a number of leading zeros of the value in the representation of the other format 714, calculating a weight based on the number of leading zeros 716, performing a shift of the intermediate fraction value in a specified direction based on a shift amount determined based on the weight to provide a resulting fraction 718, and using the resulting fraction to provide the converted result 720.

By using the hardware device to perform the plurality of operations as part of executing an instruction, performance is improved, and use of system resources is reduced. Further, the speed at which conversions are performed is increased without losing precision compared to a software solution.

Further, in one example, referring to FIG. 7B, the hardware device (e.g., a decimal floating point unit) 700 is to provide the converted result in the other format to be used in processing within the computing environment 722.

In one aspect, the hardware device includes a conversion component 730 to scale the input value to provide the scaled result 732 and to perform at least part of the converting, the at least part of the converting including converting the scaled result in the one format to provide a value in a representation of the other format 734.

Further, in one aspect, the hardware device includes a count leading zeros component 740 to determine a number of leading zeros of the value in the representation of the other format 742. In one aspect, the count leading zeros component is to determine a number of leading zeros of one part of an intermediate fraction value split into one part and another part 744, and to determine a number of leading zeros of the other part 746.

In one aspect, the hardware device includes an exponent component 750 to obtain the number of leading zeros to be determined by the count leading zeros component 752 and to calculate a weight based on the number of leading zeros 754.

Further, in one aspect, the hardware device includes an arithmetic component 760 to produce an intermediate fraction value in the other format based on the value in the representation of the other format 762. In one example, the arithmetic component is to truncate the resulting fraction to provide a truncated fraction of a given precision, the truncated fraction to be used to provide one portion of the converted result in the other format 766. Further, in one example, the arithmetic component is to round the resulting fraction to provide a rounded fraction of a given precision, the rounded fraction to be used to provide one portion of the converted result in the other format 768.

In one aspect, referring to FIG. 7C, the hardware device includes a shift component 770 to obtain a shift amount based on the weight to be calculated by the exponent component, to obtain the intermediate fraction value in the other format to be produced by the arithmetic component 772, to perform a shift of the intermediate fraction value in a specified direction based on the shift amount to produce a resulting fraction 774, and, in one aspect, to split the intermediate fraction value into one part and another part 776.

In one aspect, the hardware device includes a normalize component 780 to shift the one part a specified direction and a specified amount based at least on the number of leading zeros of the one part 782, to shift the other part a specified direction and a specified amount based at least on the number of leading zeros of the other part 784, to truncate remaining digits in a prespecified direction of the one part to provide a truncated one part 786, to truncate remaining digits in a prespecified direction of the other part to provide a truncated other part 788, to move the truncated one part to a low order fractional part of the converted result in the other format 790 and to move the truncated other part to a high order fractional part of the converted result in the other format 792.

In one aspect, the resulting fraction is used to provide one portion of the converted result 794, and another portion of the converted result, based on the input value and the weight, is provided 796.

By using the hardware device to perform the plurality of operations as part of executing an instruction, performance is improved, and use of system resources is reduced. Further, the speed at which conversions are performed is increased without losing precision compared to a software solution.

In one or more aspects, an input binary coded decimal number is scaled and converted, using a decimal floating point unit, into, at least, a hexadecimal fraction number. For instance, the input binary coded decimal number is shifted and a conversion loop is started, in which the shifted input binary coded decimal number is converted into a hexadecimal fraction number. A hexadecimal fraction of a hexadecimal floating point number is provided according to a predefined output format (defined by, e.g., a modifier field in an instruction).

Although embodiments are described herein, other variations and/or embodiments are possible.

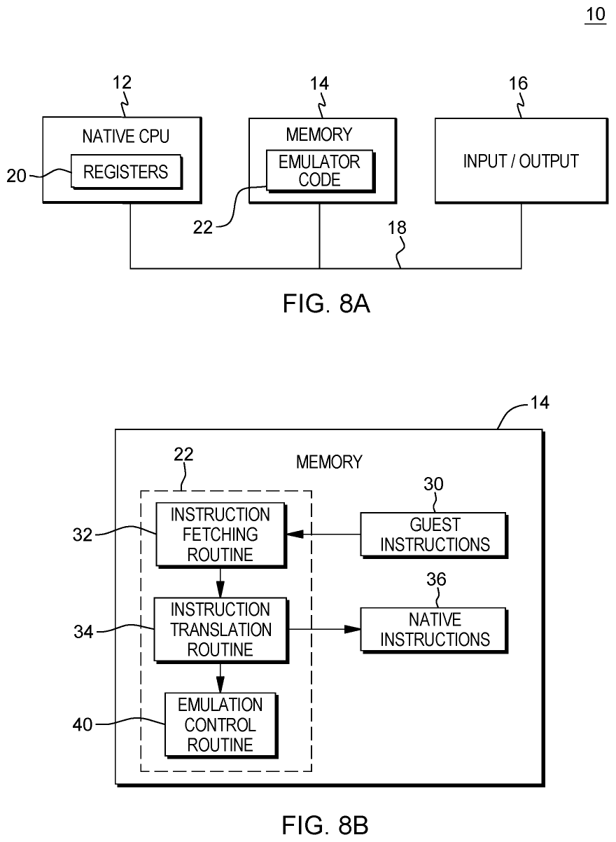

Aspects of the present invention and/or results provided by one or more aspects of the present invention may be used by many types of computing environments. Another example of a computing environment to incorporate and use one or more aspects of the present invention and/or to execute transactions that use results of one or more aspects of the present invention is described with reference to FIG. 8A. In this example, a computing environment 10 includes, for instance, a native central processing unit (CPU) 12, a memory 14, and one or more input/output devices and/or interfaces 16 coupled to one another via, for example, one or more buses 18 and/or other connections. As examples, computing environment 10 may include an IBM® Power® processor offered by International Business Machines Corporation, Armonk, N.Y.; an HP Superdome with Intel® processors offered by Hewlett Packard Co., Palo Alto, Calif.; and/or other machines based on architectures offered by International Business Machines Corporation, Hewlett Packard, Intel Corporation, Oracle, or others. Power is a trademark or registered trademark of International Business Machines Corporation in at least one jurisdiction. Intel is a trademark or registered trademark of Intel Corporation or its subsidiaries in the United States and other countries.

Native central processing unit 12 includes one or more native registers 20, such as one or more general purpose registers and/or one or more special purpose registers used during processing within the environment. These registers include information that represents the state of the environment at any particular point in time.

Moreover, native central processing unit 12 executes instructions and code that are stored in memory 14. In one particular example, the central processing unit executes emulator code 22 stored in memory 14. This code enables the computing environment configured in one architecture to emulate another architecture. For instance, emulator code 22 allows machines based on architectures other than, e.g., the IBM® z/Architecture® instruction set architecture, such as Power processors, HP Superdome servers or others, to emulate the z/Architecture instruction set architecture and to execute software and instructions developed based on the z/Architecture instruction set architecture.

Further details relating to emulator code 22 are described with reference to FIG. 8B. Guest instructions 30 stored in memory 14 comprise software instructions (e.g., correlating to machine instructions) that were developed to be executed in an architecture other than that of native CPU 12. For example, guest instructions 30 may have been designed to execute on a processor based on the z/Architecture instruction set architecture, but instead, are being emulated on native CPU 12, which may be, for example, an Intel processor. In one example, emulator code 22 includes an instruction fetching routine 32 to obtain one or more guest instructions 30 from memory 14, and to optionally provide local buffering for the instructions obtained. It also includes an instruction translation routine 34 to determine the type of guest instruction that has been obtained and to translate the guest instruction into one or more corresponding native instructions 36. This translation includes, for instance, identifying the function to be performed by the guest instruction and choosing the native instruction(s) to perform that function.

Further, emulator code 22 includes an emulation control routine 40 to cause the native instructions to be executed. Emulation control routine 40 may cause native CPU 12 to execute a routine of native instructions that emulate one or more previously obtained guest instructions and, at the conclusion of such execution, return control to the instruction fetch routine to emulate the obtaining of the next guest instruction or a group of guest instructions. Execution of the native instructions 36 may include loading data into a register from memory 14; storing data back to memory from a register; or performing some type of arithmetic or logic operation, as determined by the translation routine.

Each routine is, for instance, implemented in software, which is stored in memory and executed by native central processing unit 12. In other examples, one or more of the routines or operations are implemented in firmware, hardware, software or some combination thereof. The registers of the emulated processor may be emulated using registers 20 of the native CPU or by using locations in memory 14. In embodiments, guest instructions 30, native instructions 36 and emulator code 22 may reside in the same memory or may be disbursed among different memory devices.

The computing environments described above are only examples of computing environments that can be used. Other environments, including but not limited to, non-partitioned environments, partitioned environments, cloud environments and/or emulated environments, may be used; embodiments are not limited to any one environment. Although various examples of computing environments are described herein, one or more aspects of the present invention may be used with many types of environments. The computing environments provided herein are only examples.

Each computing environment is capable of being configured to include one or more aspects of the present invention. For instance, each may be configured to perform conversion of one data format to another data format, to execute transactions that use results of the conversion, and/or perform one or more other aspects of the present invention.

Although various embodiments are described herein, many variations and other embodiments are possible without departing from a spirit of aspects of the present invention. It should be noted that, unless otherwise inconsistent, each aspect or feature described herein, and variants thereof, may be combinable with any other aspect or feature.

One or more aspects may relate to cloud computing.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

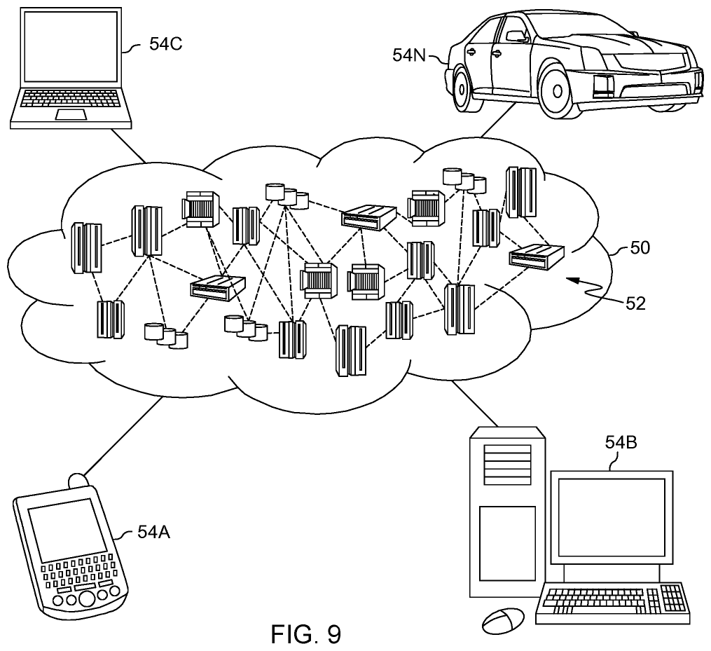

Referring now to FIG. 9, illustrative cloud computing environment 50 is depicted. As shown, cloud computing environment 50 includes one or more cloud computing nodes 52 with which local computing devices used by cloud consumers, such as, for example, personal digital assistant (PDA) or cellular telephone 54A, desktop computer 54B, laptop computer 54C, and/or automobile computer system 54N may communicate. Nodes 52 may communicate with one another. They may be grouped (not shown) physically or virtually, in one or more networks, such as Private, Community, Public, or Hybrid clouds as described hereinabove, or a combination thereof. This allows cloud computing environment 50 to offer infrastructure, platforms and/or software as services for which a cloud consumer does not need to maintain resources on a local computing device. It is understood that the types of computing devices 54A-N shown in FIG. 9 are intended to be illustrative only and that computing nodes 52 and cloud computing environment 50 can communicate with any type of computerized device over any type of network and/or network addressable connection (e.g., using a web browser).

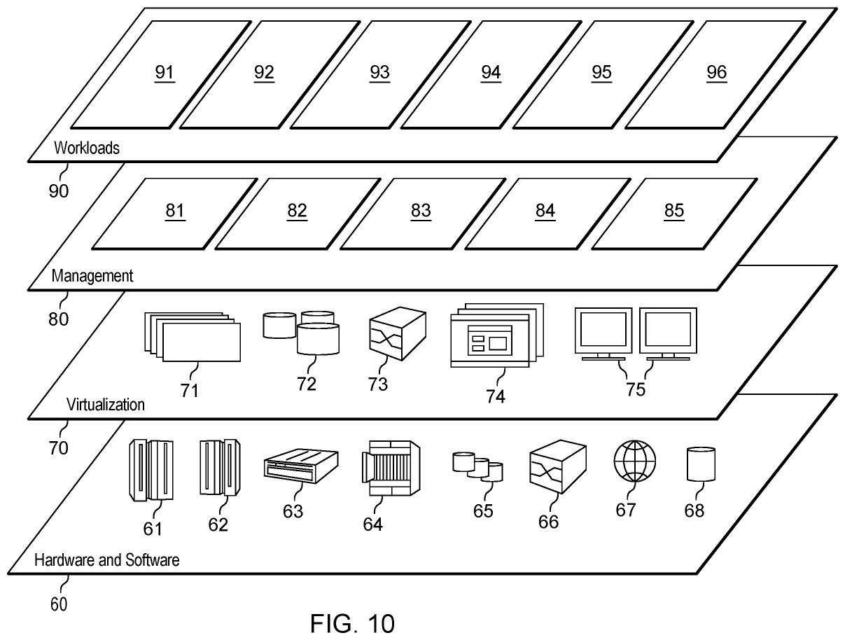

Referring now to FIG. 10, a set of functional abstraction layers provided by cloud computing environment 50 (FIG. 9) is shown. It should be understood in advance that the components, layers, and functions shown in FIG. 10 are intended to be illustrative only and embodiments of the invention are not limited thereto. As depicted, the following layers and corresponding functions are provided:

Hardware and software layer 60 includes hardware and software components. Examples of hardware components include: mainframes 61; RISC (Reduced Instruction Set Computer) architecture based servers 62; servers 63; blade servers 64; storage devices 65; and networks and networking components 66. In some embodiments, software components include network application server software 67 and database software 68.

Virtualization layer 70 provides an abstraction layer from which the following examples of virtual entities may be provided: virtual servers 71; virtual storage 72; virtual networks 73, including virtual private networks; virtual applications and operating systems 74; and virtual clients 75.

In one example, management layer 80 may provide the functions described below. Resource provisioning 81 provides dynamic procurement of computing resources and other resources that are utilized to perform tasks within the cloud computing environment. Metering and Pricing 82 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 83 provides access to the cloud computing environment for consumers and system administrators. Service level management 84 provides cloud computing resource allocation and management such that required service levels are met. Service Level Agreement (SLA) planning and fulfillment 85 provide pre-arrangement for, and procurement of, cloud computing resources for which a future requirement is anticipated in accordance with an SLA.

Workloads layer 90 provides examples of functionality for which the cloud computing environment may be utilized. Examples of workloads and functions which may be provided from this layer include: mapping and navigation 91; software development and lifecycle management 92; virtual classroom education delivery 93; data analytics processing 94; transaction processing 95; and conversion processing 96.

Aspects of the present invention may be a system, a method, and/or a computer program product at any possible technical detail level of integration. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

In addition to the above, one or more aspects may be provided, offered, deployed, managed, serviced, etc. by a service provider who offers management of customer environments. For instance, the service provider can create, maintain, support, etc. computer code and/or a computer infrastructure that performs one or more aspects for one or more customers. In return, the service provider may receive payment from the customer under a subscription and/or fee agreement, as examples. Additionally, or alternatively, the service provider may receive payment from the sale of advertising content to one or more third parties.

In one aspect, an application may be deployed for performing one or more embodiments. As one example, the deploying of an application comprises providing computer infrastructure operable to perform one or more embodiments.

As a further aspect, a computing infrastructure may be deployed comprising integrating computer readable code into a computing system, in which the code in combination with the computing system is capable of performing one or more embodiments.

As yet a further aspect, a process for integrating computing infrastructure comprising integrating computer readable code into a computer system may be provided. The computer system comprises a computer readable medium, in which the computer medium comprises one or more embodiments. The code in combination with the computer system is capable of performing one or more embodiments.

Although various embodiments are described above, these are only examples. For example, different components of a hardware device and/or other hardware devices may be used. Further, other data formats may be represented. Many variations are possible.

Various aspects are described herein. Further, many variations are possible without departing from a spirit of aspects of the present invention. It should be noted that, unless otherwise inconsistent, each aspect or feature described herein, and variants thereof, may be combinable with any other aspect or feature.

Further, other types of computing environments can benefit and be used. As an example, a data processing system suitable for storing and/or executing program code is usable that includes at least two processors coupled directly or indirectly to memory elements through a system bus. The memory elements include, for instance, local memory employed during actual execution of the program code, bulk storage, and cache memory which provide temporary storage of at least some program code in order to reduce the number of times code must be retrieved from bulk storage during execution.

Input/output or I/O devices (including, but not limited to, keyboards, displays, pointing devices, DASD, tape, CDs, DVDs, thumb drives and other memory media, etc.) can be coupled to the system either directly or through intervening I/O controllers. Network adapters may also be coupled to the system to enable the data processing system to become coupled to other data processing systems or remote printers or storage devices through intervening private or public networks. Modems, cable modems, and Ethernet cards are just a few of the available types of network adapters.

The terminology used herein is for the purpose of describing particular embodiments only and is not intended to be limiting. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components and/or groups thereof.

The corresponding structures, materials, acts, and equivalents of all means or step plus function elements in the claims below, if any, are intended to include any structure, material, or act for performing the function in combination with other claimed elements as specifically claimed. The description of one or more embodiments has been presented for purposes of illustration and description but is not intended to be exhaustive or limited to in the form disclosed. Many modifications and variations will be apparent to those of ordinary skill in the art. The embodiment was chosen and described in order to best explain various aspects and the practical application, and to enable others of ordinary skill in the art to understand various embodiments with various modifications as are suited to the particular use contemplated.

What is claimed is:

1. A computer system for facilitating processing within a computing environment, the computer system comprising:
a hardware device to perform a plurality of operations to convert an input value directly from one format to another format, the hardware device to perform the plurality of operations based on execution of an instruction, the plurality of operations comprising:
scaling the input value to provide a scaled result; and
converting the scaled result from the one format to provide a converted result in the another format, the scaling and converting to be performed as part of executing the instruction; and
wherein the hardware device is to provide the converted result in the another format to be used in processing within the computing environment.

2. The computer system of claim 1, wherein the one format is a binary coded decimal format and the another format is a hexadecimal floating point format.

3. The computer system of claim 1, wherein the hardware device comprises a conversion component, the conversion component to scale the input value to provide the scaled result.

4. The computer system of claim 3, wherein the conversion component is to perform at least part of the converting, the at least part of the converting including converting the scaled result in the one format to provide a value in a representation of the another format.

5. The computer system of claim 4, wherein the hardware device further comprises an arithmetic component to produce an intermediate fraction value in the another format based on the value in the representation of the another format.

6. The computer system of claim 5, wherein the hardware device further comprises a count leading zeros component to determine a number of leading zeros of the value in the representation of the another format.

7. The computer system of claim 6, wherein the hardware device further comprises an exponent component, the exponent component to obtain the number of leading zeros to be determined by the count leading zeros component and to calculate a weight based on the number of leading zeros.

8. The computer system of claim 7, wherein the hardware device further comprises a shift component, the shift component to obtain a shift amount based on the weight to be calculated by the exponent component, to obtain the intermediate fraction value in the another format to be produced by the arithmetic component and to perform a shift of the intermediate fraction value in a specified direction based on the shift amount to produce a resulting fraction.

9. The computer system of claim 8, wherein the arithmetic component is to truncate the resulting fraction to provide a truncated fraction of a given precision, the truncated fraction to be used to provide one portion of the converted result in the another format.

10. The computer system of claim 8, wherein the arithmetic component is to round the resulting fraction to provide a rounded fraction of a given precision, the rounded fraction to be used to provide one portion of the converted result in the another format.

11. The computer system of claim 8, wherein the resulting fraction is used to provide one portion of the converted result, and wherein at least one component of the hardware device is to provide another portion of the converted result based on the input value and the weight.

12. The computer system of claim 5, wherein the hardware device further comprises a shift component and a count leading zeros component, the shift component to obtain the intermediate fraction value in the another format to be produced by the arithmetic component and to split the intermediate fraction value into one part and another part, the count leading zeros component to determine a number of leading zeros of the one part and a number of leading zeros of the another part.

13. The computer system of claim 12, wherein the hardware device further comprises a normalize component to shift the one part a specified direction and a specified amount based at least on the number of leading zeros of the one part, to truncate remaining digits in a prespecified direction of the one part to provide a truncated one part and to move the truncated one part to a low order fractional part of the converted result in the another format.

14. The computer system of claim 12, wherein the hardware device further comprises a normalize component to shift the another part a specified direction and a specified amount based at least on the number of leading zeros of the another part, to truncate remaining digits in a prespecified direction of the another part to provide a truncated another part and to move the truncated another part to a high order fractional part of the converted result in the another format.

15. The computer system of claim 1, wherein the hardware device is a decimal floating point unit.

16. The computer system of claim 1, wherein the converting includes:
converting the scaled result in the one format to provide a value in a representation of the another format;
producing an intermediate fraction value in the another format based on the value in the representation of the another format;
determining a number of leading zeros of the value in the representation of the another format;
calculating a weight based on the number of leading zeros;
performing a shift of the intermediate fraction value in a specified direction based on a shift amount determined based on the weight to provide a resulting fraction; and
using the resulting fraction to provide the converted result.

17. A computer-implemented method of facilitating processing within a computing environment, the computer-implemented method comprising:
performing, by a hardware device of the computing environment, a plurality of operations to convert an input value directly from one format to another format, the hardware device to perform the plurality of operations based on execution of an instruction, the plurality of operations comprising:
scaling the input value to provide a scaled result; and
converting the scaled result from the one format to provide a converted result in the another format, the scaling and converting to be performed as part of executing the instruction; and
providing the converted result in the another format to be used in processing within the computing environment.

18. The computer-implemented method of claim 17, wherein the converting includes:
converting the scaled result in the one format to provide a value in a representation of the another format;
producing an intermediate fraction value in the another format based on the value in the representation of the another format;
determining a number of leading zeros of the value in the representation of the another format;
calculating a weight based on the number of leading zeros;
performing a shift of the intermediate fraction value in a specified direction based on a shift amount determined based on the weight to provide a resulting fraction; and
using the resulting fraction to provide the converted result.

19. The computer-implemented method of claim 17, wherein the converting includes:
converting the scaled result in the one format to provide a value in a representation of the another format; and
producing an intermediate fraction value in the another format based on the value in the representation of the another format.

20. The computer-implemented method of claim 19, wherein the converting further includes:
splitting the intermediate fraction value into one part and another part;
shifting the one part a specified direction and a specified amount;
shifting the other part another specified direction and another specified amount;
truncating remaining digits in a prespecified direction of the one part to provide a truncated one part;
truncating remaining digits in another prespecified direction of the another part to provide a truncated another part;
moving the truncated one part to a low order fractional part of the converted result in the another format; and
moving the truncated another part to a high order fractional part of the converted result in the another format.
